(19) United States
(12) Patent Application Publication
(10) Pub. No.: US 2026/0319389 A1
(43) Pub. Date: Oct. 15, 2026

(54) MEASURING METHOD, SHAPING METHOD, ARTICLE MANUFACTURING METHOD, MEASURING APPARATUS, AND SHAPING APPARATUS

(71) Applicant: CANON KABUSHIKI KAISHA, Tokyo (JP)

(72) Inventors: RYO NAKAYAMA, Tochigi (JP); TAKAFUMI MIYAHARU, Tochigi (JP); WATARU YAMAGUCHI, Tochigi (JP); KAZUKI OTA, Tochigi (JP); TOMOYA TAKAHASHI, Tochigi (JP)

(21) Appl. No.: 19/633,173

(22) Filed: Mar. 30, 2026

(30) Foreign Application Priority Data
Apr. 10, 2025 (JP) 2025-065201

(51) Int. Cl. G03F 9/00; G03F 7/00

(52) U.S. Cl. CPC G03F 9/7042; G03F 7/0002; G03F 9/7076; G03F 9/7084; G03F 9/7092

(57) ABSTRACT

The present disclosure provides a measuring method of measuring, in shaping a composition on a substrate by using a mold, a relative positional deviation between the mold and the substrate, wherein the relative positional deviation is determined based on images obtained by capturing a first moire fringe formed by a first mold mark and a first substrate mark, a second moire fringe formed by a second mold mark and a second substrate mark, a third moire fringe formed by a third mold mark and a third substrate mark, and a fourth moire fringe formed by a fourth mold mark and a fourth substrate mark.

### BACKGROUND

### Field of the Technology

The present disclosure relates to a measuring method, a shaping method, an article manufacturing method, a measuring apparatus, and a shaping apparatus.

### Description of the Related Art

An imprint apparatus that transfers the concave-convex pattern of a mold onto a composition on a substrate is attracting much attention as one of lithography apparatuses for manufacturing articles such as semiconductor devices and magnetic storage media. The imprint apparatus measures the relative positional deviation between a mold and a substrate to perform alignment between the mold and the substrate. The relative positional deviation can be measured based on the image obtained by capturing an image of the moire fringe formed by a mark on a mold and a mark on a substrate each having a line-and-space structure. In capturing a moire fringe image, scattered light (reflected light) from the concave-convex pattern (device pattern) of the mold may exert influence on this image capturing operation. In this case, a measurement error can occur in the result of measuring the relative positional deviation between the mold and the substrate based on the image. As one method of reducing the influence of scattered light from such a concave-convex pattern, there is available a method of inclining the array direction of lines of a mark having a line-and-space structure with respect to the pattern region of the mold (see, for example, Japanese Patent No. 7544781).

In order to accurately align a mold with a substrate in an imprint apparatus, there is a need to further accurately measure the relative positional deviation between the mold and the substrate. That is, the technique disclosed in Japanese Patent No. 7544781 has room for improvement.

### SUMMARY

The present disclosure provides a technique advantageous in accurately measuring the relative positional deviation between a mold and a substrate.

According to one aspect of the present disclosure, there is provided a measuring method of measuring, in shaping a composition on a substrate by using a mold that has a rectangular pattern region, a relative positional deviation between the mold and the substrate, wherein the mold includes a first mold mark having lines arrayed at a first pitch in a first direction inclined with respect to one side of the pattern region, a second mold mark having lines arrayed at the first pitch in a second direction perpendicular to the first direction, a third mold mark having lines arrayed at a second pitch different from the first pitch in the first direction, and a fourth mold mark having lines arrayed at the second pitch in the second direction, wherein the substrate includes a first substrate mark having lines arrayed at the second pitch so as to form a first moire fringe in pair with the first mold mark, a second substrate mark having lines arrayed at the second pitch so as to form a second moire fringe in pair with the second mold mark, a third substrate mark having lines arrayed at the first pitch so as to form a third moire fringe in pair with the third mold mark, and a fourth substrate mark having lines arrayed at the first pitch so as to form a fourth moire fringe in pair with the fourth mold mark, and wherein the measuring method determines the relative positional deviation based on images obtained by capturing the first moire fringe, the second moire fringe, the third moire fringe, and the fourth moire fringe.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing a configuration example of an imprint apparatus according to one embodiment;

FIGS. 2A and 2B are schematic views showing a configuration example of a mold according to one embodiment;

FIGS. 3A to 3C are schematic views showing a configuration example of a detector (image capturing device) according to one embodiment;

FIGS. 4A and 4B are views for explaining problems concerning a mold mark and a substrate mark according to the related art;

FIG. 5 is a view showing configuration examples of a mold mark and a substrate mark according to one embodiment;

FIG. 6 is a flowchart showing a method of measuring the relative positional deviation between a mold and a substrate according to one embodiment;

FIG. 7 is a conceptual view for explaining a method of calculating relative positional deviations in the X and Y directions from relative positional deviations in the first and second directions; and

FIGS. 8A to 8F are views for explaining an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

One aspect of the present disclosure relates to a measuring method and a measuring apparatus which measure the relative positional deviation between an original plate (mold) and a substrate. The measuring method and the measuring apparatus according to the present disclosure can be used to perform alignment between an original plate and a substrate in a lithography apparatus, and more particularly, to perform alignment between a mold and a substrate in a shaping apparatus and can also be applied to other apparatuses such as a processing apparatus, an inspection apparatus, and a microscope.

A shaping apparatus to which the measuring method and the measuring apparatus according to the present disclosure are applied is an apparatus that performs a shaping process of shaping a composition on a substrate using a mold. Examples of the shaping apparatus are an imprint apparatus and a planarization apparatus. The imprint apparatus is an apparatus that brings a mold including a concave-convex pattern (a pattern having concave and convex portions) into contact with a composition (imprint material) on a substrate to form (transfer) the pattern on the composition. The shaping process performed by the imprint apparatus will sometimes be referred to as an imprint process hereinafter. The planarization apparatus is an apparatus that planarizes the surface of a composition on a substrate by bringing a mold including a flat surface into contact with the composition. The shaping process performed by the planarization apparatus will sometimes be referred to as a planarization process hereinafter. The imprint apparatus will be exemplified as the shaping apparatus below, but the configuration and process of the imprint apparatus can also be applied to the planarization apparatus.

The imprint apparatus can be configured to bring a mold (original plate) into contact with an imprint material arranged on a substrate, cure the imprint material by applying curing energy to the imprint material, and form a pattern formed from the cured product of the imprint material on the substrate.

As the imprint material, a curable composition (to be also referred to as a resin in an uncured state) to be cured by receiving curing energy is used. As the curing energy, an electromagnetic wave, heat, or the like can be used. The electromagnetic wave can be, for example, light selected from the wavelength range of 10 nm (inclusive) to 1 mm (inclusive), for example, infrared light, visible light, or ultraviolet light. The curable composition can be a composition cured by light irradiation or heating. Among these, the photo-curable composition cured by light irradiation contains at least a polymerizable compound and a photopolymerization initiator, and may further contain a nonpolymerizable compound or a solvent, as needed. The nonpolymerizable compound is at least one type of material selected from a group consisting of a sensitizer, a hydrogen donor, an internal mold release agent, a surfactant, an antioxidant, a polymer component, and the like. The imprint material can be arranged on the substrate in a droplet shape or in an island or film shape formed by connecting a plurality of droplets using an imprint material supplying apparatus (not shown). The viscosity (the viscosity at 25° C.) of the imprint material can be, for example, 1 mPa·s (inclusive) to 100 mPa·s (inclusive). In addition, as the material of the substrate, for example, glass, a ceramic, a metal, a semiconductor, a resin, or the like can be used. A member made of a material different from that of the substrate may be provided on the surface of the substrate, as needed. The substrate is, for example, a silicon wafer, a compound semiconductor wafer, or silica glass.

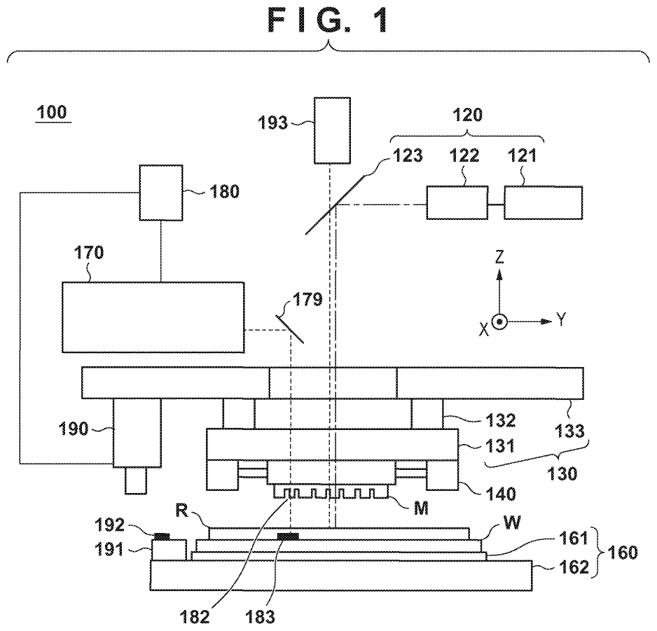

FIG. 1 schematically shows a configuration example of an imprint apparatus 100 according to one embodiment. In this specification and the accompanying drawings, directions will be indicated in an XYZ coordinate system in which a horizontal plane is an X-Y plane. In general, a substrate W such as a wafer is placed on a substrate stage 162 such that the surface of the substrate W is parallel to the horizontal plane (X-Y plane). Accordingly, in the specification and the accompanying drawings, directions orthogonal to each other within a plane along the surface of the substrate W are respectively defined as the X-axis and the Y-axis, and a direction perpendicular to the X-axis and the Y-axis is defined as the Z-axis. Directions parallel to the X-axis, the Y-axis, and the Z-axis of the XYZ coordinate system are the X direction, the Y direction, and the Z direction, respectively. Rotating directions about the X-axis, the Y-axis, and the Z-axis are respectively defined as θX-axis, θY-axis, and θZ-axis directions.

For example, the imprint apparatus 100 is a UV light curing imprint apparatus that cures an imprint material by irradiation with UV light (ultraviolet light). The imprint apparatus 100 may be an imprint apparatus that cures an imprint material by irradiation with light in another wavelength region or may be an imprint apparatus that cures an imprint material using another type of energy (for example, heat).

The imprint apparatus 100 can be configured to form a pattern on each of a plurality of shot regions on the substrate W by repeating imprint processing. The imprint processing can be the processing of forming a pattern on one shot region on the substrate W by curing an imprint material R placed on the substrate W while a mold Mis in contact with the imprint material R.

The imprint apparatus 100 can include, for example, a curing device 120, a mold operating mechanism 130, a mold shape correcting mechanism 140, a substrate driver 160, a detector 170, a supplier 190, an observation scope 193, and a controller 180. Although not shown, the imprint apparatus 100 can include a bridge platen that supports the mold operating mechanism 130 and a base platen that supports the substrate driver 160.

The curing device 120 can cure the imprint material R on the substrate W by irradiating the imprint material R with light (for example, ultraviolet light) through the mold M. In this case, the imprint material R can be an ultraviolet curable resin. The curing device 120 can include, for example, a light source device 121, an optical system 122, and a half mirror 123.

The light source device 121 can include, for example, a light source, such as a mercury lamp, which generates ultraviolet light (for example, i-rays or g-rays) and an elliptic mirror that collects the light generated by the light source. The optical system 122 can include, for example, a lens and an aperture which are configured to irradiate the imprint material R on a shot region with light for curing the imprint material R. Light passing through the optical system 122 can be reflected by the half mirror 123 and applied on the imprint material R. The aperture is used for angle-of-view control and peripheral light shielding control. Performing angle-of-view control makes it possible to illuminate only a target shot region with light. Performing peripheral light shielding control makes it possible to limit ultraviolet light from irradiating a region outside a target shot region. The optical system 122 may include an optical integrator for uniformly irradiating the mold M with light. Light whose range is defined by the aperture enters the imprint material R on the substrate W through the half mirror 123 and the mold M.

The mold operating mechanism 130 can include, for example, a mold chuck 131 that holds the mold M, a mold driving mechanism 132 that drives the mold M by driving the mold chuck 131, and a mold base 133 that supports the mold driving mechanism 132. The mold driving mechanism 132 can include a positioning mechanism that controls the position of the mold M with respect to six axes and a mechanism that brings the mold M into contact with the imprint material R on the substrate W and separates the mold M from the cured imprint material R. The six axes correspond to the X, Y, Z, θX, θY, and θZ directions.

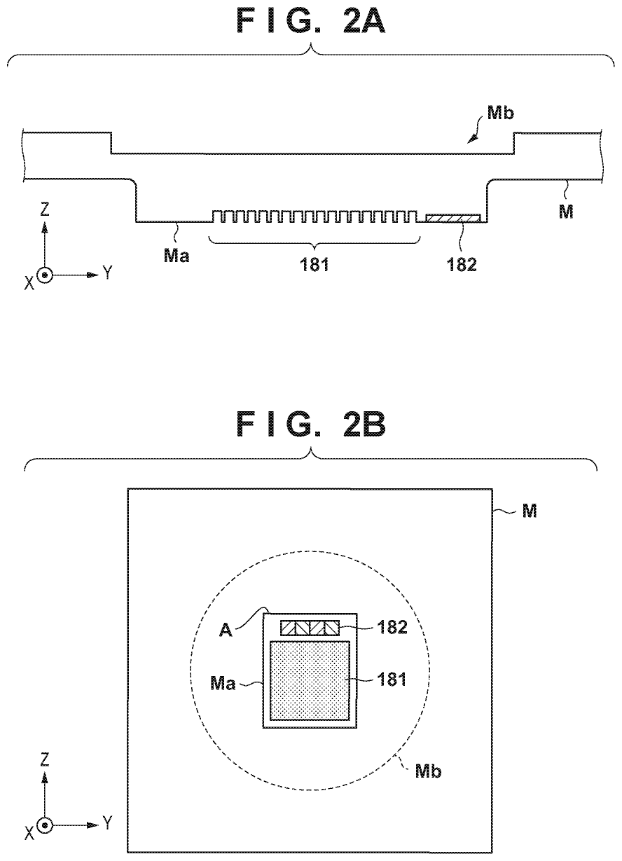

FIGS. 2A and 2B show a configuration example of the mold M according to the present embodiment. FIG. 2A is a sectional view of the mold M. FIG. 2B is a view of the mold M seen from above (the +Z direction side). In general, the mold M can be formed from a material that can transmit light (for example, ultraviolet light), such as silica glass. The mold M has a rectangular pattern region Ma on which a concave-convex pattern 181 that should be transferred onto the imprint material R on the substrate W, such as a circuit pattern (device pattern), is formed. The pattern region Ma of the mold M functions as a shaping surface that shapes the imprint material R (composition) on the substrate W and can be configured in a mesa shape (convex shape) protruding beyond its surrounding region, for example, as a stepped portion with a height of about several tens of μm. The inside of the pattern region Ma of the mold M is provided with a mark 182 (alignment mark) for measuring the relative positional deviation between the mold M and the substrate W. The opposite side of the mold M to the pattern region Ma is provided with a cavity Mb whose internal pressure is adjusted to deform the pattern region Ma into the convex shape. In the present embodiment, the mark 182 is provided inside the pattern region Ma but may be provided outside the pattern region Ma. Note that 90% or more (preferably 95% or more) of the shaping surface (contact surface) of a mold, used in a planarization apparatus, which comes into contact with a composition on a substrate to shape the composition can be configured as a flat surface without any concave-convex pattern.

The mold shape correcting mechanism 140 can be mounted on the mold chuck 131. The mold shape correcting mechanism 140 can correct the shape of the mold M (the pattern region Ma thereof) by pressurizing the peripheral side surface of the mold M using an actuator such as a cylinder that operates with a fluid such as air or oil or a piezoelectric element. Alternatively, the mold shape correcting mechanism 140 includes a temperature controller that controls the temperature of the mold M and can correct the shape of the mold M (the pattern region Ma thereof) by controlling the temperature of the mold M. The substrate W can deform (typically, expand or contract) through a process such as heat treatment. The mold shape correcting mechanism 140 can correct the shape of the mold M in accordance with such deformation of the substrate W such that the overlay error between the pattern of the mold M and the existing pattern on the substrate W falls within an allowable range.

The substrate driver 160 can include, for example, a substrate chuck 161, the substrate stage 162, a reference mark base 191, and a stage driving mechanism (not shown). The substrate chuck 161 can hold the substrate W by suction. The substrate stage 162 supports the substrate chuck 161 and moves the substrate W by driving the substrate chuck 161. The stage driving mechanism (not shown) can include a positioning mechanism that controls the position of the substrate W by controlling the position of the substrate stage 162 with respect to the six axes described above. The reference mark base 191 provided with a reference mark 192 can be provided on the substrate stage 162. In this case, the mold driving mechanism 132 of the mold operating mechanism 130 and the substrate driver 160 (stage driving mechanism) can constitute a relative driver that relatively drives the mold M and the substrate W.

The detector 170 is part of a measuring apparatus that measures the relative positional deviation between the mold M and the substrate W (shot region) and detects the mark 182 (alignment mark) provided on the mold M and a mark 183 (alignment mark) provided on the substrate W. In the present embodiment, the mark 182 on the mold M has a line-and-space structure. The mark 183 on the substrate W also has a line-and-space structure so as to form a moire fringe in pair with the mark 182 on the mold M. The detector 170 can be configured as an image capturing device that illuminates the mark 182 on the mold M and the mark 183 on the substrate W and captures (detects) an image of the moire fringe (interference fringe) formed by the light diffracted by the marks 182 and 183.

In the following description, the relative positional deviation between the mold M and the substrate W may simply be referred to as “relative positional deviation”. In addition, the mark 182 provided on the mold M may be referred to as “mold mark 182”, and the mark 183 provided on the substrate W may be referred to as “substrate mark 183”.

The controller 180 is configured as, for example, a computer (information processing apparatus) including a processor such as a central processing unit (CPU) and a storage device such as a memory and controls imprint processing by controlling each device of the imprint apparatus 100. The controller 180 is implemented by, for example, a programmable logic device (PLD) such as a field programmable gate array (FPGA), an application specific integrated circuit (ASIC), a general-purpose or dedicated computer installed with a program, or a combination of all or some of them. In addition, the controller 180 can perform the processing of determining the relative positional deviation between the mold M and the substrate W based on the image captured by the detector 170 (image capturing device). That is, in the imprint apparatus 100 according to the present embodiment, the detector 170 (image capturing device) and the controller 180 can constitute a measuring apparatus that measures the relative positional deviation between the mold M and the substrate W.

The supplier 190 can be configured as a dispenser that supplies the imprint material R onto the substrate W. The supplier 190 can include a tank storing the imprint material R, a nozzle that discharges the imprint material R supplied from the tank through a supply path to the substrate W, a valve provided in the supply path, and a supply amount controller.

The observation scope 193 is a scope for observing the shot regions of the substrate W and has an image capturing element for capturing an image of a shot region. The observation scope 193 can be used to check, for example, the state of contact between the mold M and the imprint material R and the progress of filling the concave portion of the concave-convex pattern provided in the pattern region Ma of the mold M with the imprint material R.

Imprint processing by the imprint apparatus 100 will be described next. First of all, a substrate transfer apparatus (not shown) transfers the substrate W onto the substrate chuck 161 and fixes the substrate W on the substrate chuck 161 under the control of the controller 180. Subsequently, the stage driving mechanism moves the substrate stage 162 so as to place a shot region of the substrate W immediately below the mold M under the control of the controller 180. The mold driving mechanism 132 then lowers the mold M and brings the mold M into contact with the imprint material R on the substrate W under the control of the controller 180 (contact step).

When the mold M comes into contact with the imprint material R, the imprint material R flows along the surface of the pattern region Ma of the mold M and fills the space between the pattern region Ma and the substrate W and the concave portion of the pattern provided on the pattern region Ma. While the mold M is in contact with the imprint material R, the detector 170 can detect (capture an image of) the moire fringe formed by reflected diffracted light from the mold mark 182 and the substrate mark 183. The controller 180 can determine the relative positional deviation between the mold M and the substrate W based on an output (image) from the detector 170 and execute alignment between the mold M and the substrate W based on the relative positional deviation. Alignment between the mold M and the substrate W can include relative driving between the mold M and the substrate W by the substrate stage 162 and shape correction of the pattern region of the mold M by the mold shape correcting mechanism 140.

Subsequently, the curing device 120 applies light from the back surface (upper surface) of the mold M to cure the imprint material R with the light transmitted through the mold M (curing step) under the control of the controller 180. The mold driving mechanism 132 then drives the mold M upward and separates the mold M from the cured imprint material R under the control of the controller 180 (mold releasing step). This transfers the pattern of the mold M onto the imprint material R on the substrate W.

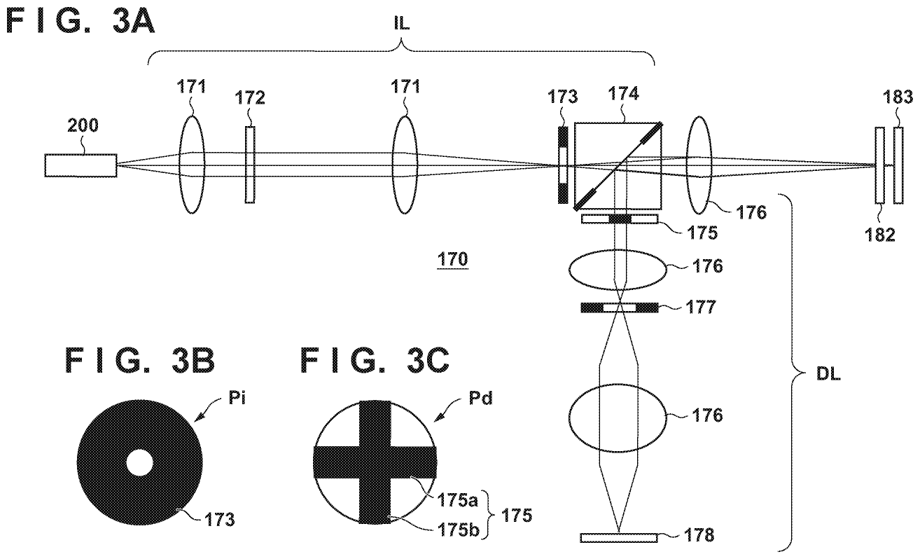

FIG. 3A is a schematic view showing a configuration example of the detector 170 (image capturing device) according to one embodiment. FIG. 3A shows only an optical system for measurement in a single direction (for example, the X direction) in order to facilitate describing the optical system. According to the above description made with reference to FIG. 1, light emerging from the detector 170 illuminates the mold mark 182 and the substrate mark 183 after the direction of the light is changed by a mirror 179. FIG. 3A omits the illustration of the mirror 179 for the sake of simplicity.

The detector 170 can include a light source 200, an illumination optical system IL, and a detection optical system DL (image capturing optical system). In the present embodiment, as described above, the mold mark 182 and the substrate mark 183 each have a line-and-space structure. The detector 170 can be configured to capture an image of the moire fringe formed by the mold mark 182 and the substrate mark 183.

The illumination optical system IL can be configured to illuminate the mold mark 182 and the substrate mark 183 with light from the light source 200. For example, the illumination optical system IL can include a plurality of lenses 171, an illumination field stop 172, an illumination aperture stop 173 (first aperture stop), and a beam splitter 174. As shown in FIG. 3B, the illumination aperture stop 173 can be configured to form a small σ illumination by light-shielding a peripheral region of a pupil plane Pi (first pupil plane) of the illumination optical system IL and letting light pass through a central region of the pupil plane Pi. FIG. 3B shows the pupil plane Pi of the illumination optical system IL. The black portion is the light-shielding region formed by the illumination aperture stop 173, and the white portion is the light passing region.

The detection optical system DL can include the beam splitter 174, a detection aperture stop 175 (second aperture stop), a plurality of lenses 176, a detection field stop 177, and an image capturing element 178. As shown in FIG. 3C, the detection aperture stop 175 can be configured to light-shield a cross-shaped region of a pupil plane Pd (second pupil plane) of the detection optical system DL and let light pass through the remaining regions (quadrupole regions). More specifically, the detection aperture stop 175 light-shields two band-shaped regions 175a and 175b intersecting (orthogonal to) each other at the center of gravity of the pupil plane Pd in the pupil plane Pd of the detection optical system DL. FIG. 3C shows the pupil plane Pd of the detection optical system DL. The black portion is the light-shielding region formed by the detection aperture stop 175, and the white portions are light passing regions.

As shown in FIGS. 3B and 3C, forming the illumination aperture stop 173 and the detection aperture stop 175 makes it possible to reduce unnecessary light and further improve the detection accuracy with respect to the mold mark 182 and the substrate mark 183. In this case, as the image capturing element 178 of the detection optical system DL, for example, an image sensor (photoelectric conversion element) such as a CMOS sensor or a CCD sensor can be used.

In detecting (capturing an image of) the moire fringe formed by the mold mark 182 and the substrate mark 183 with the detector 170, the detection may be influenced by scattered light (reflected light) from the concave-convex pattern 181 in the pattern region Ma and the like. For example, as shown in FIGS. 2A and 2B, the pattern region Ma of the mold M according to the present embodiment has a mesa shape, and the mold mark 182 is placed near the concave-convex pattern 181 in the pattern region Ma. Accordingly, when scattered light from the concave-convex pattern 181 exerts influence on the detection (image capturing) of the marks 182 and 183 with the detector 170, a measurement error can occur in the result of measuring the relative positional deviation between the mold M and the substrate W based on the image obtained by the detector 170.

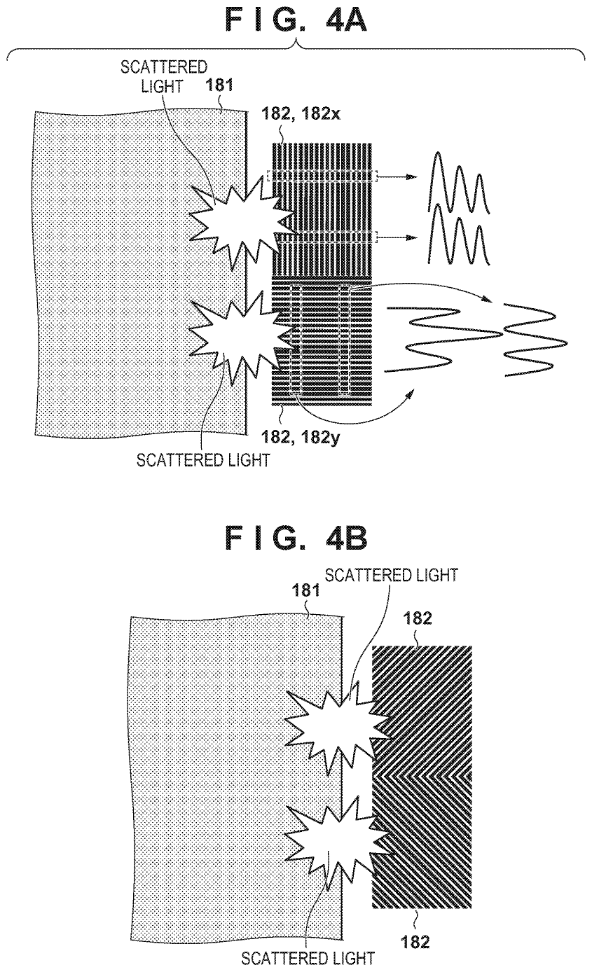

Conventionally, as shown in FIG. 4A, the mold M is provided with a mold mark 182x having lines arrayed in a direction (X direction) perpendicular to one side of the pattern region Ma and a mold mark 182y having lines arrayed in a direction (Y direction) parallel to the one side. The substrate W is also provided with two types of substrate marks 183 (not shown) having lines arrayed in the same directions as those of the mold marks 182x and 182y so as to form moire fringes in pairs with the mold marks 182x and 182y.

However, using the two types of mold marks 182x and 182y described above will make the signal intensity distribution of the moire fringes on the image obtained by the detector 170 greatly differ in symmetry in the X direction and the Y direction because the influence of scattered light increases with a decrease in distance to the concave-convex pattern 181. That is, the symmetry of the signal intensity distribution (in the X direction) of the moire fringe on the image obtained by the detector 170 using the mold mark 182x greatly differs from the symmetry of the signal intensity distribution (in the Y direction) of the moire fringe on the image obtained by the detector 170 using the mold mark 182y. This can make it difficult to accurately measure the relative positional deviation between the mold M and the substrate W.

In contrast, as shown in FIG. 4B, inclining the array directions of the lines of the two types of mold marks 182 with respect to one side of the pattern region Ma can reduce the difference in symmetry between the signal intensity distributions of the two types of mold marks 182. In particular, inclining the array directions of the lines of the two types of mold marks 182 by 45° with respect to one side of the pattern region Ma will make the symmetries of the signal intensity distributions of the two types of mold marks 182 exhibit similar tendencies, thereby further reducing the difference in symmetry. The present embodiment will exemplify a technique of accurately measuring the relative positional deviation between the mold M and the substrate W in the use of the mold marks 182 having lines arrayed in directions inclined with respect to one side of the pattern region Ma.

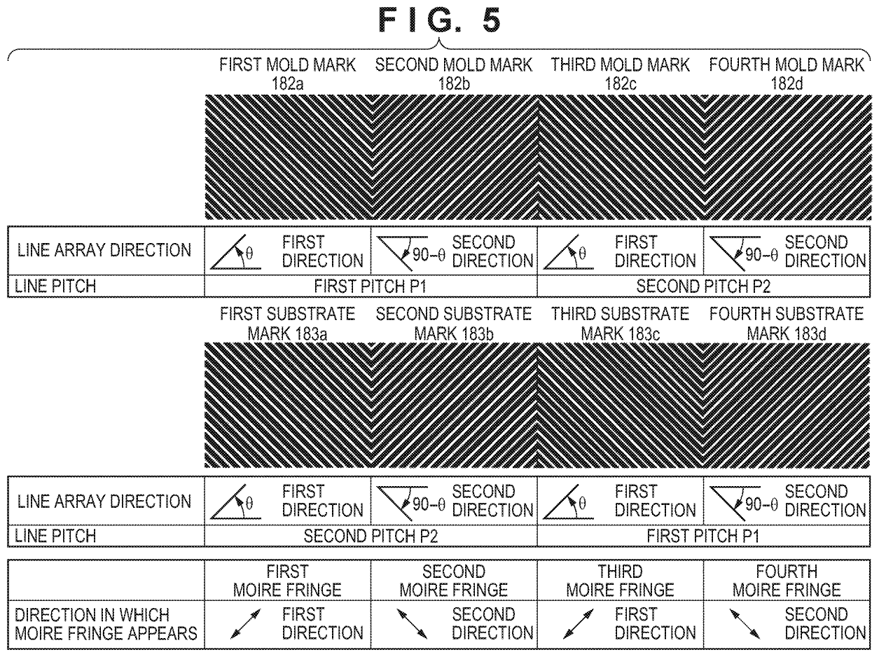

FIG. 5 shows configuration examples of the mold mark 182 and the substrate mark 183 according to the present embodiment. The present embodiment can use the plurality of mold marks 182 and the plurality of substrate marks 183 that form moire fringes in pairs with the plurality of mold marks 182.

The plurality of mold marks 182 can include a first mold mark 182a, a second mold mark 182b, a third mold mark 182c, and a fourth mold mark 182d. As shown in FIG. 2B, the mold marks 182a to 182d can be arranged near one side A of the rectangular pattern region Ma along the one side A (that is, a direction parallel to the one side A). Limitation is not made to the order of the mold marks 182a to 182d arranged along the one side A of the pattern region Ma. In addition, the mold marks 182a to 182d may be provided with respect to at least two sides of the four sides of the rectangular pattern region Ma as well as with respect to the one side A of the rectangular pattern region Ma.

The first mold mark 182a has a line-and-space structure having lines arrayed at a first pitch P1 in the first direction inclined with respect to the one side A of the pattern region Ma. The first direction is a direction inclined at an angle of +45° with respect to the one side A of the pattern region Ma. The second mold mark 182b has a line-and-space structure having lines arrayed at the first pitch P1 in the second direction perpendicular to the first direction. The second direction is a direction inclined at an angle of −45° with respect to the one side A of the pattern region Ma. The third mold mark 182c has a line-and-space structure having lines arrayed at a second pitch P2 in the first direction. The second pitch P2 is a pitch (interval) different from the first pitch P1. The fourth mold mark 182d has a line-and-space structure having lines arrayed at the second pitch P2 in the second direction.

The plurality of substrate marks 183 can include a first substrate mark 183a, a second substrate mark 183b, a third substrate mark 183c, and a fourth substrate mark 183d. The substrate marks 183a to 183d can be arranged in the scribe region of the substrate W. The scribe region is a region between two adjacent shot regions of a plurality of shot regions to each of which the pattern of the pattern region Ma of the mold M is transferred.

The first substrate mark 183a has a line-and-space structure having lines arrayed at the second pitch P2 in the first direction so as to form the first moire fringe in pair with the first mold mark 182a. The second substrate mark 183b has a line-and-space structure having lines arrayed at the second pitch P2 in the second direction so as to form the second moire fringe in pair with the second mold mark 182b. The third substrate mark 183c has a line-and-space structure having lines arrayed at the first pitch P1 in the first direction so as to form the third moire fringe in pair with the third mold mark 182c. The fourth substrate mark 183d has a line-and-space structure having lines arrayed at the first pitch P1 in the second direction so as to form the fourth moire fringe in pair with the fourth mold mark 182d.

The detector 170 (image capturing device) captures images of the first moire fringe, the second moire fringe, the third moire fringe, and the fourth moire fringe respectively formed by the mold marks 182a to 182d and the substrate marks 183a to 183d described above. The period of each moire fringe can be expressed by equation (1) given below:

$$T = \frac{P 1 P 2}{2 \vert P 1 - P 2 \vert} \qquad ( 1 )$$

In addition, the controller 180 determines the relative positional deviation between the mold M and the substrate W based on the image obtained by the detector 170. For example, the controller 180 determines a relative positional deviation expressed by a first-direction component and a second-direction component by performing period analysis on each of the first moire fringe, the second moire fringe, the third moire fringe, and the fourth moire fringe on the image. The first-direction component is a direction component (parallel-direction component) parallel to the one side A of the pattern region Ma and is an X-direction component in the present embodiment. The second-direction component is a direction component (vertical-direction component) vertical to the one side A of the pattern region Ma and is a Y-direction component in the present embodiment.

The controller 180 can determine (calculate) the X-direction component (first-direction component) and the Y-direction component (second-direction component) of a relative positional deviation according to equation (2) given below. In equation (2), the X-direction component of the relative positional deviation is represented by “shift x”, the Y-direction component of the relative positional deviation is represented by “shift y”, and the angle of the first direction with respect to the one side A of the pattern region Ma is represented by “θ”. “κ” represents a constant. In addition, “L1_{FFTX}” represents the X-direction component obtained by frequency analysis with respect to the first moire fringe, and “L2_{FFTY}” represents the Y-direction component obtained by frequency analysis with respect to the second moire fringe. “R1_{FFTX}” represents the X-direction component obtained by frequency analysis with respect to the third moire fringe, and “R2_{FFTY}” represents the Y-direction component obtained by frequency analysis with respect to the fourth moire fringe.

$$( \begin{matrix}shift x \\ shift y\end{matrix} ) = \frac{1}{κ} ( \begin{matrix}cos ( - θ ) & - sin ( - θ ) \\ sin ( - θ ) & cos ( - θ )\end{matrix} ) ( \begin{matrix}( L {1}_{FFTX} - R {1}_{FFTX} ) / 2 \\ ( L {2}_{FFTY} - R {2}_{FFTY} ) / 2\end{matrix} ) \qquad ( 2 )$$

In this case, frequency analysis includes Fourier transform (one-dimensional Fourier transform or two-dimensional Fourier transform). That is, “L1_{FFTX}” is obtained by performing one-dimensional Fourier transform or two-dimensional Fourier transform with respect to the first moire fringe (signal intensity distribution) of the image. The same applies to “R1_{FFTX}”, “L2_{FFTY}”, “R2_{FFTY}”. The controller 180 extracts the result of the moire period obtained by equation (1) from an X-direction component “shift x” and a Y-direction component “shift y” of the relative positional deviation obtained by equation (2). This makes it possible to determine the relative positional deviations between the mold M and the substrate W in the X direction and the Y direction.

Example indicates a case where first pitch P1=880 nm, second pitch P2=800 nm, and angle θ=45°. In this case, the period of each of moire fringes in the first direction inclined at an angle of −45° with respect to the one side A of the pattern region Ma and the second direction inclined at an angle of +45° with respect to the one side A is “4.4 μm” according to equation (1). The period of each moire fringe in each of the X direction and the Y direction is √2 times the period of each of moire fringes in the first direction and the second direction and hence is “6.2 μm”. The controller 180 can determine the relative positional deviations between the mold M and the substrate W in the X direction and the Y direction by calculating equation (2) by inputting “angle 0=45°” thereto and extracting a frequency component of 6.2 μm.

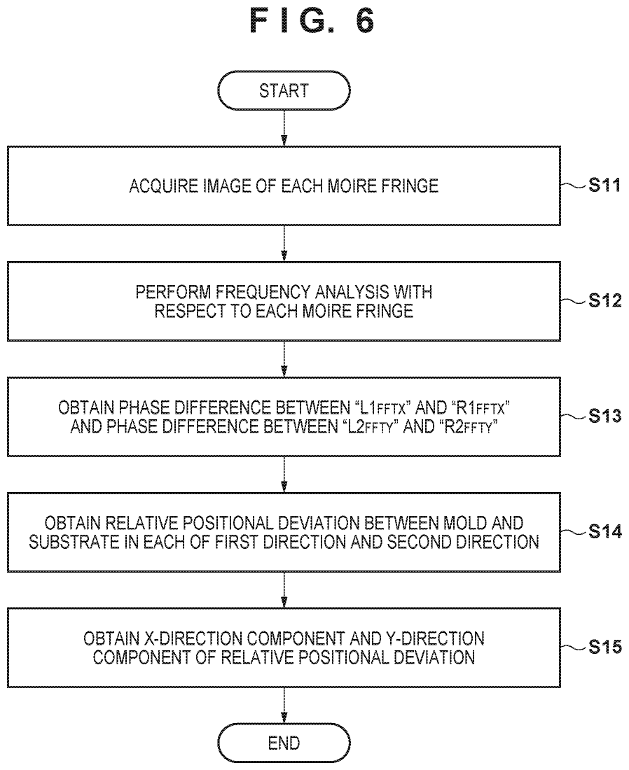

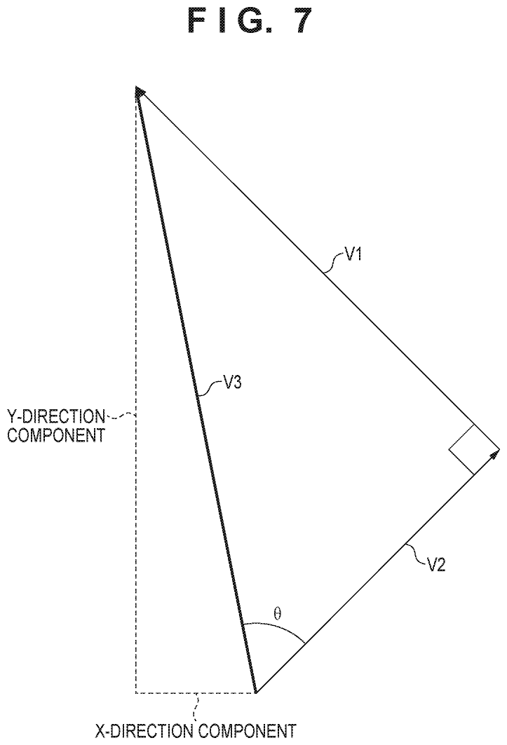

FIG. 6 is a flowchart showing a measuring method for the relative positional deviation between the mold M and the substrate W according to the present embodiment. The controller 180 can execute the flowchart of FIG. 6. FIG. 7 shows a conceptual view for explaining a method of calculating the relative positional deviations between the mold M and the substrate W in the X direction and the Y direction from the relative positional deviations between the mold M and the substrate W in the first direction and the second direction.

In step S11, the controller 180 causes the detector 170 to capture images of the first moire fringe, the second moire fringe, the third moire fringe, and the fourth moire fringe and acquires the image of each moire fringe from the detector 170. In step S12, the controller 180 performs frequency analysis (for example, Fourier transform) with respect to each moire fringe. This makes it possible to obtain “L1_{FFTX}”, “R1_{FFTX}”, “L2_{FFTY}”, and “R2_{FFTY}”.

In step S13, the controller 180 obtains the phase difference between “L1_{FFTX}” and “R1_{FFTX}” and the phase difference between “L2_{FFTY}” and “R2_{FFTY}”. For example, the controller 180 can obtain the phase difference between “L1_{FFTX}” and “R1_{FFTX}” from the difference between them. Likewise, the controller 180 can obtain the phase difference between “L2_{FFTY}” and “R2_{FFTY}” from the difference between them.

In step S14, the controller 180 obtains the relative positional deviation between the mold M and the substrate W in each of the first direction and the second direction based on the phase difference information obtained in step S13. For example, the controller 180 can obtain the relative positional deviation between the mold M and the substrate W in the first direction based on the phase difference information between “L1_{FFTX}” and “R1_{FFTX}” obtained in step S13 and the period information of a reference moire fringe. Likewise, the controller 180 can obtain the relative positional deviation between the mold M and the substrate W in the second direction based on the phase difference information between “L2_{FFTY}” and “R2_{FFTY}” obtained in step S13 and the period information of the reference moire fringe. As shown in FIG. 7, this makes it possible to obtain a vector v1 as information obtained from the second moire fringe and the fourth moire fringe and a vector V2 as information obtained from the first moire fringe and the third moire fringe. In this case, period information is information indicating the period of reference moire fringe designed for evaluation and can be acquired in advance based on, for example, the design data of each mold mark 182 and each substrate mark 183.

In step S15, the controller 180 determines the X-direction component and the Y-direction component of the relative positional deviation between the mold M and the substrate W based on the relative positional deviation between the mold M and the substrate W obtained in each of the first direction and the second direction in step S14. For example, as shown in FIG. 7, the controller 180 obtains a vector V3 by combining the vector v1 and the vector V2 and can determine the X-direction component and the Y-direction component of the vector V3 as the X-direction component and the Y-direction component of the relative positional deviation between the mold M and the substrate W. In this case, in imprint processing, the relative positional deviation between the mold M and the substrate W is calculated by using the above measuring method, and alignment between the mold M and the substrate W can be controlled based on the measurement result.

As described above, in the present embodiment, the relative positional deviation between the mold M and the substrate W is determined based on the images obtained by capturing images of the first to fourth moire fringes formed by the plurality of mold marks 182a to 182d and the plurality of substrate marks 183a to 183d. Using the four types of moire fringes in this manner makes it possible to accurately measure the relative positional deviation between the mold M and the substrate W. Although the present embodiment described above has exemplified the case where the marks forming the first to fourth moire fringes are continuously arranged, the marks can be arranged separately.

### <Embodiment of Article Manufacturing Method>

An article manufacturing method according to the embodiment of the present disclosure is suitable for manufacturing an article, for example, a microdevice such as a semiconductor device or an element having a microstructure. The article manufacturing method according to the present embodiment includes a shaping step of shaping a composition on a substrate using the above-described shaping apparatus, a processing step of processing the substrate having the composition shaped in the shaping step, and a manufacturing step of manufacturing an article from the substrate processed in the processing step. An imprint apparatus or a planarization apparatus can be used as the shaping apparatus. The article manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product shaped using the above-described shaping apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. An example of the mold is a mold for imprint.

The pattern of the cured product is directly used as the constituent member of at least some of the above-described articles or used temporarily as a resist mask. After etching or ion implantation is performed in the substrate processing step, the resist mask is removed.

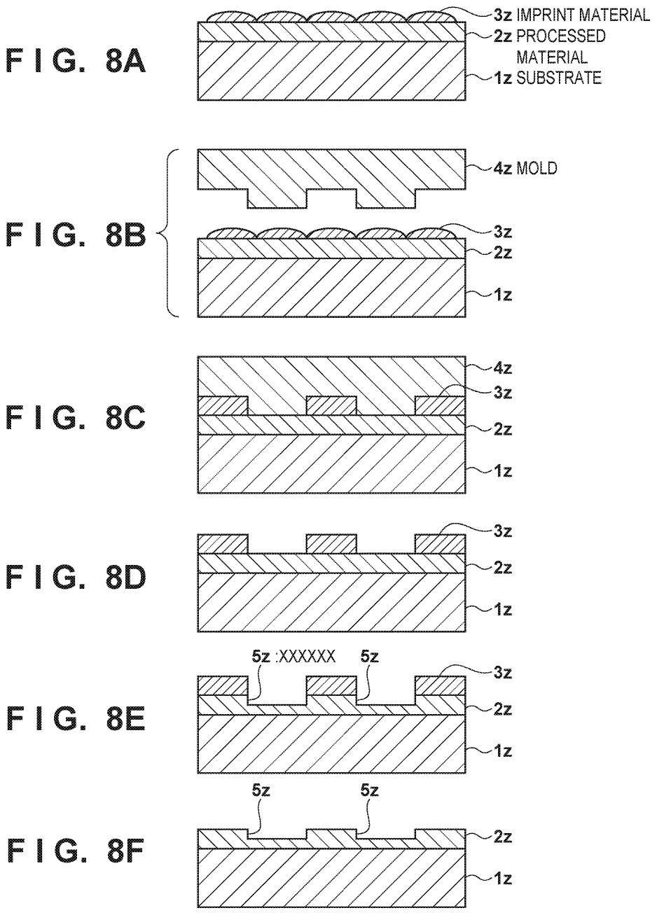

A practical article manufacturing method in a case where an imprint apparatus is used as the shaping apparatus will be described next. As shown in FIG. 8A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 8B, a side of a mold 4z for imprint with a concave-convex pattern is directed to face the imprint material 3z on the substrate. As shown in FIG. 8C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 8D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As shown in FIG. 8E, when etching is performed using the pattern of the cured product as an etching resistant mask, a portion of the surface of the processed material 2z where the cured product does not exist or remains thin is removed to form a groove 5z. As shown in FIG. 8F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### OTHER EMBODIMENTS

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-065201, filed on Apr. 10, 2025, which is hereby incorporated by reference herein in its entirety.

What is claimed is:

1. A measuring method of measuring, in shaping a composition on a substrate by using a mold that has a rectangular pattern region, a relative positional deviation between the mold and the substrate,
wherein the mold includes a first mold mark having lines arrayed at a first pitch in a first direction inclined with respect to one side of the pattern region, a second mold mark having lines arrayed at the first pitch in a second direction perpendicular to the first direction, a third mold mark having lines arrayed at a second pitch different from the first pitch in the first direction, and a fourth mold mark having lines arrayed at the second pitch in the second direction,
wherein the substrate includes a first substrate mark having lines arrayed at the second pitch so as to form a first moire fringe in pair with the first mold mark, a second substrate mark having lines arrayed at the second pitch so as to form a second moire fringe in pair with the second mold mark, a third substrate mark having lines arrayed at the first pitch so as to form a third moire fringe in pair with the third mold mark, and a fourth substrate mark having lines arrayed at the first pitch so as to form a fourth moire fringe in pair with the fourth mold mark, and
wherein the measuring method determines the relative positional deviation based on images obtained by capturing the first moire fringe, the second moire fringe, the third moire fringe, and the fourth moire fringe.

2. The method according to claim 1, wherein the lines of each of the first substrate mark and the third substrate mark are arrayed in the first direction, and the lines of each of the second substrate mark and the fourth substrate mark are arrayed in the second direction.

3. The method according to claim 1, wherein the first mold mark, the second mold mark, the third mold mark, and the fourth mold mark are arranged along the one side of the pattern region.

4. The method according to claim 1, wherein
the pattern region is formed in a mesa shape protruding beyond a surrounding region thereof, and
the first mold mark, the second mold mark, the third mold mark, and the fourth mold mark are arranged near the one side of the pattern region.

5. The method according to claim 1, wherein the first direction is inclined at an angle of 45° with respect to the one side of the pattern region.

6. The method according to claim 1, wherein the first mold mark, the second mold mark, the third mold mark, and the fourth mold mark are respectively provided with respect to at least two sides of the four sides of the pattern region.

7. The method according to claim 1, wherein the relative positional deviation expressed by a first-direction component parallel to the one side of the pattern region and a second-direction component perpendicular to the one side is determined by performing a frequency analysis with respect to each of the first moire fringe, the second moire fringe, the third moire fringe, and the fourth moire fringe in the images.

8. The method according to claim 7, wherein the frequency analysis includes one-dimensional Fourier transform or two-dimensional Fourier transform.

9. The method according to claim 7, wherein letting “shift x” be the first-direction component of the relative positional deviation, “shift y” be the second-direction component of the relative positional deviation, “0” be an angle of the first direction with respect to the one side, “L1_{FFTX}” be the first-direction component obtained by the frequency analysis on the first moire fringe, “L2_{FFTY}” be the second-direction component obtained by the frequency analysis on the second moire fringe, “R1_{FFTX}” be the first-direction component obtained by the frequency analysis on the third moire fringe, “R2_{FFTY}” be the second-direction component obtained by the frequency analysis on the fourth moire fringe, and “K” be a constant, the relative positional deviation is determined by
$$( \begin{matrix}shift x \\ shift y\end{matrix} ) = \frac{1}{κ} ( \begin{matrix}cos ( - θ ) & - sin ( - θ ) \\ sin ( - θ ) & cos ( - θ )\end{matrix} ) ( \begin{matrix}( L {1}_{FFTX} - R {1}_{FFTX} ) / 2 \\ ( L {2}_{FFTY} - R {2}_{FFTY} ) / 2\end{matrix} )$$

10. A shaping method of shaping a composition on a substrate by using a mold, the method comprising:
measuring a relative positional deviation between a mold and a substrate by using a measuring method defined in claim 1; and
aligning the mold and the substrate based on a measurement result obtained in the measuring.

11. An article manufacturing method comprising:
shaping a composition on a substrate by using a shaping method defined in claim 10;
processing the substrate having the shaped composition; and
manufacturing an article from the processed substrate.

12. A measuring apparatus that measures, in shaping a composition on a substrate by using a mold that has a rectangular pattern region, a relative positional deviation between the mold and the substrate, the apparatus comprising:
an image capturing device configured to capture an image of a moire fringe formed by a mark on the mold and a mark on the substrate; and
a controller configured to determine the relative positional deviation based on images obtained by the image capturing device,
wherein the mold includes a first mold mark having lines arrayed at a first pitch in a first direction inclined with respect to one side of the pattern region, a second mold mark having lines arrayed at the first pitch in a second direction perpendicular to the first direction, a third mold mark having lines arrayed at a second pitch different from the first pitch in the first direction, and a fourth mold mark having lines arrayed at the second pitch in the second direction,
wherein the substrate includes a first substrate mark having lines arrayed at the second pitch so as to form a first moire fringe in pair with the first mold mark, a second substrate mark having lines arrayed at the second pitch so as to form a second moire fringe in pair with the second mold mark, a third substrate mark having lines arrayed at the first pitch so as to form a third moire fringe in pair with the third mold mark, and a fourth substrate mark having lines arrayed at the first pitch so as to form a fourth moire fringe in pair with the fourth mold mark, and
wherein the controller determines the relative positional deviation based on images obtained by capturing the first moire fringe, the second moire fringe, the third moire fringe, and the fourth moire fringe by using the image capturing device.

13. The apparatus according to claim 12, wherein the image capturing device includes a first aperture stop configured to light-shield a peripheral region of a first pupil plane through which illumination light illuminating a mark passes and a second aperture stop configured to light-shield two band-shaped regions intersecting each other at a center of gravity of a second pupil plane in the second pupil plane through which reflected light from the mark passes.

14. A shaping apparatus that shapes a composition on a substrate by using a mold, the apparatus comprising:
a measuring apparatus defined in claim 12; and
a driver configured to relatively drive the mold and the substrate,
wherein alignment between the mold and the substrate is controlled by using the driver based on a measurement result obtained by the measuring apparatus.
